(19) United States
(12) Patent Application Publication
(10) Pub. No.: US 2025/0008753 A1
(43) Pub. Date: Jan. 2, 2025

(54) PEROVSKITE SOLAR CELL

(71) Applicant: MEYER BURGER (GERMANY) GMBH, Hohenstein-Ernstthal (DE)

(72) Inventor: Hermann-Josef NONNENMACHER, Leipzig (DE)

(73) Assignee: MEYER BURGER (GERMANY) GMBH, Hohenstein-Ernstthal (DE)

(21) Appl. No.: 18/710,136

(22) PCT Filed: Nov. 22, 2022
(86) PCT No.: PCT/DE2022/100874

§ 371 Date: May 14, 2024

(30) Foreign Application Priority Data
Nov. 23, 2021 (DE) 10 2021 130 591.8

(51) Int. Cl. H10K 30/57; H10K 30/40; H10K 30/85; H10K 30/86

(52) U.S. Cl. CPC H10K 30/57; H10K 30/40; H10K 30/85; H10K 30/86

(57) ABSTRACT

The invention relates to a perovskite solar cell. The perovskite solar cell is either a single solar cell or at least one sub-cell of a multi-junction solar cell. The perovskite solar cell has: an absorber made of a perovskite material, an electron transport layer which is conductively connected to at least one negative contact of the perovskite solar cell, and a hole transport layer which is conductively connected to at least one positive contact of the perovskite solar cell, wherein the electron transport layer serves as a hole reflector, and the hole transport layer serves as an electron reflector. The aim of the invention is to provide simple functional perovskite solar cells which are nevertheless inexpensive. This is achieved by a perovskite solar cell in which the electron transport layer and/or the hole transport layer and/or at least one passivation layer for the absorber layer is a layer based on deposited silicon

The present invention relates to a perovskite solar cell, wherein the perovskite solar cell is either a single-junction solar cell or at least one sub-cell of a multi-junction solar cell, wherein the perovskite solar cell has: an absorber made from a perovskite material, an electron transport layer, connected in a conductive manner with at least one negative contact of the perovskite solar cell, a hole transport layer, connected in a conductive manner with at least one positive contact of the perovskite solar cell; wherein the electron transport layer is used as a hole reflector and the hole transport layer is used as an electron reflector. Furthermore, the invention also relates to the method for producing such a solar cell.

Perovskite solar cells are thin-film solar cells that are being researched by many working groups worldwide, on which impressive progress has been made in recent years, and which are currently believed by experts to be capable of achieving industrial significance in the future. In contrast to silicon, which is a semiconductor material frequently used in solar cell production, it is more difficult to produce both of the dopants required to create a p-n junction in the perovskite class of semiconductor materials. The perovskite material is therefore provided as an undoped or only lightly doped layer, which acts as a solar absorber. The energy of solar photons is mainly utilized in the absorber to generate electron-hole pairs. In order to provide the holes at the positive contact and the electrons at the negative contact of the solar cell, an electron transport material and a hole transport material are regularly provided in direct or indirect contact with the absorber, which conduct one type of charge carrier (n or p) and reflect the other type of charge carrier (p or n), so that the reflected charge carriers can still drift to the other electrode in the best case before they are lost through recombination with an oppositely charged charge carrier for utilization in an electric current outside the solar cell. The initial aim of research projects is to produce well-functioning solar cells and to gather fundamental findings. The high complexity of the structures produced and the method used often helps to separate different effects from one another and to better understand them. In research, high manufacturing costs are initially of secondary importance. Even exotic, complex and expensive materials such as a gold electrode in US 2020/0388442 A1 are considered first.

For large-scale industrial implementation and also for the present invention, however, the object is to identify simple, functional and yet cost-effective perovskite solar cells and manufacturing methods for them.

The object is achieved by a perovskite solar cell, in which the electron transport layer and/or the hole transport layer and/or at least one passivation layer for the absorber layer is a deposited silicon-based layer.

In this solar cell, at least one layer connected directly or indirectly to the perovskite absorber is therefore a low-cost silicon layer or a silicon-based layer which, in addition to silicon atoms, also contains other atoms, for the deposition of which a wealth of experience is available. The different layers of the perovskite solar cell all enable the flow of at least one of the two charge carrier types (of electrons and/or holes). The pn junction of the perovskite solar cell is formed between the electron transport layer and the hole transport layer, it is therefore located in the inner part of the perovskite cell. In the electron transport material of the electron transport layer, electrons are the majority charge carriers that are conducted to the negative contact. Holes are the minority charge carriers in the electron transport material which, in the unlikely event of formation, quickly recombine with electrons. The hole transport material of the hole transport layer has correspondingly opposite characteristics. Depending on the course of the valence bands and conduction bands between the hole transport layer, the absorber and the electron transport layer, the respective majority charge carriers are conducted into the electron transport layer or the hole transport layer either by ohmic conduction or by a tunneling mechanism. With the tunneling mechanism, the majority charge carriers can overcome narrow spike barriers which are partially designed as interfaces. As the perovskite material of the absorber, the solar cell according to the invention can comprise either a widely used methylammonium lead iodide (MAPbI₃) or another lead-containing or lead-free material. The choice of material depends, for example, on the planned use as a single solar cell, as a sub-cell in a tandem solar cell or as a sub-cell in a multi-junction solar cell. In multi-junction solar cells, the several sub-cells are each specialized for a different spectral range section of the sunlight spectrum to be used due to a differently sized band gap. In multi-junction solar cells, each multi-junction solar cell has a different sub-task and is based on a different semiconductor material that is favorable for the sub-task. The negative contact and the positive contact can be realized from transparent conductive oxides (TCOs) and/or metals. The contacts often have several components, the largest surface areas are contacted by large-area TCO layers, fine metal finger lines conduct small currents, while for larger currents, power collector lines, in particular busbars or wires (or SmartWires in the protected SmartWire Connection Technology (SWCT)) are used. The back of a solar cell can however also be large-area contacted with a metal layer. If the currents are sufficiently low, a contact can also be formed by a TCO layer alone, for example in series connections of narrow strip-shaped shingle solar cells.

According to the invention, in various embodiments, perovskite solar cells have one or more silicon-based layers, which either border directly with the absorber or are only separated physically from the absorber by at least one thin intermediary layer. The electron transport layer and the hole transport layer can be arranged either on opposite sides (i.e. both on the front facing the sun and on the opposite back) of the absorber or only on one side (i.e. on the back of back-contacted solar cells (IBC solar cells)). The at least one silicon-based layer can be connected with the negative contact or the positive contact. Also, one or more silicon layers can be arranged at both the positive contact and the negative contact and/or at a contactless frontside. Depending on whether it is a double-sided contacted solar cell or a back-contacted solar cell and which layer of the solar cell is involved, the silicon-based layer extends either essentially over the entire front or back of the solar cell or only over locally delimited back contact areas.

The perovskite cells can be produced in different production methods progressively from the back to the front by corresponding layer depositions. Alternatively, production beginning with the frontmost layer and ending with the back layer is also possible. If the perovskite solar cell is the front cell of a tandem solar cell, then the perovskite solar cell can be built up in layers by layer deposition on the lower sub-cell. Alternatively, however, the perovskite sub-cell can also be produced separately initially and be mounted on the lower sub-cell later.

The silicon layers may be amorphous silicon layers. Amorphous silicon is a semi-conductor material having a band gap of 1.7 eV, which is a little larger than the band gap of the MAPbI₃ of 1.55 eV, for example. Different layer characteristics, including the band gap, can be optimized e.g. by deposition parameters, dopants and/or post-treatment for the respective application.

In more specific cases of perovskite solar cells according to the invention, the hole transport material is p-doped amorphous silicon (p-aSi:H) and an intrinsic amorphous silicon layer (i-aSi:H) is also arranged between the absorber and the p-doped amorphous silicon as a passivation layer. The undoped amorphous silicon layer and the p-doped amorphous silicon layer can be separately deposited layers, for which separate deposition chambers are available in a deposition system. The two layers can also however have been produced one after the other in a deposition chamber in two corresponding sub-steps of a deposition method. Instead of two separate deposition steps, more than two sub-steps can also be used or a smooth transition between different parameters can be used so that a gradient layer with a gradual change in doping is formed. At least the p-doped amorphous silicon layer is a hole transport layer consisting of a hole transport material, in which the holes are the majority charge carriers and at which electrons are reflected from the absorber back into the absorber.

In some variations of the perovskite cells according to the invention, a TCO contact layer of the perovskite solar cell is also the electron transport layer (or the TCO is the electron transport material) and an undoped (i-aSi:H) and an n-doped aSi layer (n-aSi:H) are arranged between the absorber layer and the TCO contact layer. Since the band gaps of amorphous silicon and some perovskite materials are close to each other, an n-doped amorphous silicon layer is not automatically an electron transport layer which reflects holes. This is also not absolutely necessary if another layer of the solar cell, such as the TCO layer in the mentioned exemplary embodiment, is used as an electron transport layer. If the TCO layer assumes the function of the electron transport layer and holes should still reflect in the absorber, then the intermediary layers may not exceed a maximum thickness. The sum of the undoped (i-aSi:H) and the n-doped aSi layer (n-aSi:H) can be thinner than 2 nm. For example, the two layers are each 1 nm thick. The n-aSi:H layer can also be omitted, so that in this case only the i-aSi passivation layer is arranged between the absorber and the TCO electron transport layer.

Between a TCO contact layer of the perovskite solar cell, which is also simultaneously used as an electron transport layer, and the absorber, an undoped-n-doped aSi gradient layer (n*-aSi:H; n-star layer) can also be arranged. By combining an undoped amorphous silicon layer and an n-doped amorphous silicon layer to form an n-star gradient layer, a simplification of the production method and a corresponding cost saving is achieved.

The perovskite solar cell according to the invention can be arranged as a perovskite sub-cell on a silicon heterojunction sub-cell in a tandem solar cell, wherein the tandem solar cell is a two-terminal tandem solar cell, which has the following layer construction: TCO/p-aSi/i-aSi/n-Si-wafer/n*-a-Si/p-aSi/i-aSi/absorber/n*-aSi/TCO. In this solar cell, multiple options described above are combined with each other, so that as a result a tandem solar cell with a simple structure is present.

According to a further option of perovskite solar cells according to the invention, the electron transport layer and/or the hole transport layer and/or at least one passivation layer for the absorber layer is a hydrogenated nanocrystalline silicon layer (ncSi:H). In this case, at least one of the silicon layers has a crystalline structure instead of an unordered or amorphous atomic structure, wherein the dimensions of the crystals in the layer lie in the nanometer range. The crystal structure can be characterized, for example, with an optical or diffraction-based method. If the fine crystalline layers contain crystallites that are in the order of micrometers in size, they are also referred to as microcrystalline silicon layers (ucSi:H). Hydrogen is also incorporated into these layers during deposition from hydrogen-containing precursors, so that the layers are actually hydrogenated microcrystalline silicon layers (ucSi:H).

In various exemplary embodiments, the perovskite solar cell is arranged as a perovskite sub-cell on a silicon heterojunction sub-cell in a tandem solar cell, wherein the tandem solar cell is a two-terminal tandem solar cell, which has the following layer construction: TCO/p-Si/i-aSi/n-Si-wafer/i-aSi/n-Si/p-Si(6)/i-aSi(7)/absorber(4)/i-aSi/n-Si/TCO(5), wherein at least one out of the n-Si layer and/or p-Si layer is a nano- or microcrystalline silicon layer. In further exemplary embodiments, one or more of the silicon layers is substituted by a silicon alloy layer.

The electron transport layer and/or the hole transport layer and/or at least one passivation layer, passivating the absorber layer, of the perovskite solar cell according to the invention can be a hydrogenated nanocrystalline oxygen-doped silicon layer (ncSiOx:H). Expressed in other words, the silicon-based layer of the present invention is not necessarily purely a silicon layer, but the silicon layer can also be alloyed with further elements, for example with oxygen. Other elements that can be used for alloys are nitrogen and carbon.

For example, a two-terminal tandem solar cell can have the following layer construction: TCO/p-ncSiOx/i-aSi/n-Si-wafer/i-aSi/n-ncSiOx/p-ncSiOx/i-aSi/absorber/i-aSi/n-aSi/TCO. In this layer stack, the oxygen doping in the silicon in the ncSiOx layers results in higher transparency compared to undoped silicon layers. This results in higher photo currents and ultimately a higher efficiency of the solar cell. The last TCO layer in this stack can also have the function of the electron transport layer of the perovskite sub-cell.

The invention also includes a method for producing a perovskite solar cell according to the invention, wherein all layers of the solar cell are produced in corresponding process sub-steps using vacuum methods. The characteristics of thin deposited layers are strongly related to the deposition parameters used and the structural design of a solar cell is directly linked to the sequence of sub-steps used in the production method. Some method options are difficult or even impossible to recognize in the structure of the finished solar cell. It therefore makes sense to describe the production method as well as the solar cell itself.

At least one of the silicon layers can be produced with a PECVD or hot-wire CVD method. Plasma-enhanced chemical vapor deposition (PECVD) methods are characterized by high deposition rates (and correspondingly high productivity) even at low temperatures, making them compatible with temperature-sensitive HJT solar cells and perovskite absorbers. In this method, energetic activation of the gases (in particular silane) used for layer deposition occurs with the aid of a plasma. Depending on the geometry of the deposition reactor used and process parameters such as pressure, excitation frequency and excitation power density, the plasma has different characteristics that influence the reaction processes in the gas phase on the one hand and any ion bombardment of the substrate during deposition on the other hand. For example, in cases where a PECVD deposition on the perovskite absorber could damage the latter by the ion bombardment, deposition methods without ion bombardment, such as the hot-wire method, can be used for at least one of the layers. The starting gases for the various CVD methods used generally contain hydrogen, which is partly incorporated into the layers produced, so that the silicon-based layers are generally hydrogenated layers, which is not always pointed out again. If at least two layers are produced in defined succession in the method according to the invention, this can advantageously be carried out in a system specially designed for these method steps. Using such specialized systems, a production factory can be implemented in a space-saving and cost-effective manner. In addition, carrying out processing in direct succession within one system also has the advantages of high process purity and minimal transport times.

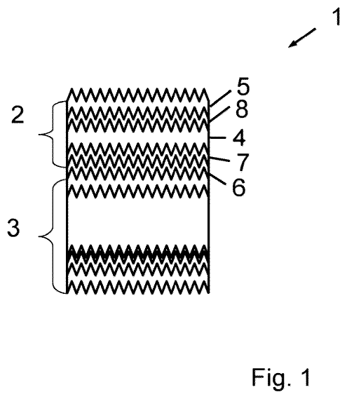

The present invention will be explained further in the following using the figure, FIG. 1, which shows an exemplary embodiment of a perovskite solar cell according to the invention as a part of a silicon perovskite tandem solar cell.

FIG. 1 outlines a section of the basic construction of an exemplary embodiment of a silicon perovskite tandem solar cell 1 having a perovskite sub-cell 2 according to the invention and a silicon heterojunction sub-cell 3.

In the exemplary embodiment shown, the silicon heterojunction sub-cell 3 is produced from an n-doped wafer. On the back shown at the bottom, a pin junction is formed via an intrinsic amorphous silicon layer and a p-doped amorphous silicon layer, as is known from the prior art. A transparent conductive metal oxide layer (TCO) represents a positive contact of the tandem solar cell 1. Furthermore, silver fingers and wire collecting electrodes (not yet shown) are involved in the formation of this positive contact, as expected by a person skilled in the art of solar cell production. On the top of the silicon heterojunction sub-cell 3, an i-n-aSi:H gradient layer provides a front surface field layer on one side for the silicon heterojunction sub-cell 3 and a first coupling layer on the other side to the perovskite sub-cell 2.

The perovskite sub-cell 2 has a p-doped amorphous hydrogenated silicon layer (p-aSi:H) in the shown exemplary embodiment on the interface to the silicon heterojunction sub-cell 3, which layer also has the function of a second coupling layer inside the tandem solar cell 1. The effect of the two coupling layers is that electrons from the silicon heterojunction sub-cell 3 and holes from the perovskite sub-cell 2 are able to recombine with each other in the coupling layers. Tunneling currents can also be involved in the conduction mechanisms. Within the perovskite sub-cell 2, the p-doped amorphous hydrogenated silicon layer (p-aSi:H) has the function of the hole transport layer 6, which only transports holes but no electrons from the perovskite sub-cell, and also serves as the positive contact of the perovskite sub-cell 2. An intrinsic amorphous silicon layer (i-aSi:H) which is used as a passivation layer is arranged between the hole transport layer 6 and the perovskite absorber layer 4.

On the front of the perovskite sub-cell 2 and the entire tandem solar cell 1, a transparent conductive metal oxide layer (TCO) is used as a contact layer and as the electron transport layer 5 of the perovskite sub-cell 2. In the exemplary embodiment shown, an undoped-n-doped aSi gradient layer 8 is arranged between the absorber 4 and the TCO layer as a passivation layer and a front field layer. Metal fingers and wires (not yet shown) are also involved in the front negative contact of the perovskite sub-cell 2 and the entire tandem cell 1.

Further exemplary embodiments result from the described options of the invention, combinations thereof and combinations with the expertise of a person skilled in the art in the field of the invention.

1-13. (canceled)

14. A perovskite solar cell, wherein the perovskite solar cell is either a single-junction solar cell or at least one sub-cell of a multi-junction solar cell, wherein the perovskite solar cell has: an absorber made from a perovskite material,
an electron transport layer, connected in a conductive manner with at least one negative contact of the perovskite solar cell,
a hole transport layer, connected in a conductive manner with at least one positive contact of the perovskite solar cell,
wherein the electron transport layer is used as a hole reflector and the hole transport layer is used as an electron reflector,
wherein the electron transport layer and/or the hole transport layer and/or at least one passivation layer passivating the absorber layer is a deposited silicon-based layer.

15. The perovskite solar cell according to claim 14, wherein the material of the hole transport layer is an amorphous p-doped silicon (p-aSi:H), wherein an intrinsic amorphous silicon layer (i-aSi:H) is arranged as a passivation layer between the absorber and the p-doped amorphous silicon.

16. The perovskite solar cell according to claim 14, wherein a TCO contact layer of the perovskite solar cell is simultaneously also the electron transport material and an undoped (i-aSi:H) and an n-doped aSi-layer (n-aSi:H) is arranged between the absorber layer and the TCO contact layer.

17. The perovskite solar cell according to claim 16, wherein the sum of the undoped (i-aSi:H) and the n-doped aSi layer (n-aSi:H) is thinner than 2 nm.

18. The perovskite solar cell according to claim 14, wherein a TCO contact layer of the perovskite solar cell is simultaneously also the electron transport material and an undoped-n-doped aSi-gradient layer (n*-aSi:H) is arranged between the absorber layer and the TCO contact layer.

19. The perovskite solar cell according to claim 14, wherein the perovskite solar cell is arranged as a perovskite sub-cell on a silicon heterojunction sub-cell in a tandem solar cell, wherein the tandem solar cell is a two-terminal tandem solar cell, which has the following layer construction:
TCO/p-aSi/i-aSi/n-Si-wafer/n*-a-Si/p-aSi(6)/i-aSi/absorber(4)/n*-aSi(8)/TCO(5).

20. The perovskite solar cell according to claim 14, wherein the electron transport layer and/or the hole transport layer and/or at least one passivation layer, passivating the absorber layer, is a hydrogenated nanocrystalline silicon layer (ncSi:H) or microcrystalline silicon layer (ucSi:H).

21. The perovskite solar cell according to claim 20, wherein the perovskite solar cell is arranged as a perovskite sub-cell on a silicon heterojunction sub-cell in a tandem solar cell, wherein the tandem solar cell is a two-terminal tandem solar cell, which has the following layer construction:
TCO/p-Si/i-aSi/n-Si-wafer/i-aSi/n-Si/p-Si(6)/i-aSi(7)/absorber(4)/i-aSi/n-Si/TCO (5), wherein at least one out of the n-Si layer and/or p-Si layer is a nano- or microcrystalline silicon layer or silicon alloy layer.

22. The perovskite solar cell according to claim 14, wherein the electron transport layer and/or the hole transport layer and/or at least one passivation layer, passivating the absorber layer, is a hydrogenated nanocrystalline silicon layer doped with oxygen (ncSiOx:H).

23. The perovskite solar cell according to claim 21, wherein the perovskite solar cell is arranged as a perovskite sub-cell on a silicon heterojunction sub-cell in a tandem solar cell, wherein the tandem solar cell is a two-terminal tandem solar cell, which has the following layer construction:
TCO/p-ncSiOx/i-aSi/n-Si-wafer/i-aSi/n-ncSiOx/p-ncSiOx/i-aSi/absorber/i-aSi/n-aSi/TCO.

24. A method for producing a perovskite solar cell according to claim 14, wherein all layers of the solar cell are produced in corresponding method sub-steps using vacuum methods.

25. The method according to claim 24, wherein at least one of the silicon-based layers is produced with a PECVD or hot-wire CVD method.

26. The method according to claim 25, wherein at least two layers are produced in defined succession in a system specially designed for these method steps.
